(19) United States
(12) Patent Application Publication
(10) Pub. No.: US 2026/0247613 A1
(43) Pub. Date: Aug. 20, 2026

(54) MEMORY DEVICE USING SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 19/451,340

(22) Filed: Jan. 16, 2026

(30) Foreign Application Priority Data
Feb. 17, 2025 (JP) 2025-023537

(51) Int. Cl. H10B 43/20; G11C 5/06; G11C 16/24; G11C 16/26; G11C 16/30; H10B 12/00; H10B 41/10; H10B 41/20; H10B 41/30; H10B 43/10; H10B 43/30

(52) U.S. Cl. CPC H10B 43/20; G11C 5/063; G11C 16/24; G11C 16/26; G11C 16/30; H10B 12/00; H10B 41/10; H10B 41/20; H10B 41/30; H10B 43/10; H10B 43/30

(57) ABSTRACT

In plan view, word line and plate line gate conductive layers WL, PL, and WL2 extending vertically and outer back gate conductive layers BG1 and BG2 are provided to sandwich channel semiconductor layers 10a and 10b parallel to a substrate 1. N⁺ regions 11aa and 11ba in contact with the layers 10a and 10b at one end are independently connected to source lines SL1 and SL2 extending vertically, and N⁺ regions 11aa and 11ab at the other end are connected to one bit line BL1 extending horizontally. During a data write/read period, a voltage of one source line SL1 or SL2 is set identical to a bit line voltage, and a voltage difference is given between the other source line and the bit line, so that a current flows therebetween. A logic "1" data write/read operation is thus performed in a memory cell of the layer 10a1 or 10a2.

### CROSS REFERENCES TO RELATED APPLICATIONS

This application claims priority to JP2025-023537, filed February 17, 2025, the entire content of which is incorporated herein by reference.

### BACKGROUND OF THE INVENTION

### 1. Field of the Invention

The present invention relates to a memory device using a semiconductor element.

### 2. Description of the Related Art

In recent years, in Large Scale Integration (LSI) technology development, higher integration and higher performance of memory elements are required.

As conventional memory elements, a Dynamic Random Access Memory (DRAM; see, for example, H. Chung, H. Kim, H. Kim, K. Kim, S. Kim, K. Dong, J. Kim, Y.C. Oh, Y. Hwang, H. Hong, G. Jin, and C. Chung: "4F2 DRAM Cell with Vertical Pillar Transistor(VPT)," 2011 Proceeding of the European Solid-State Device Research Conference, (2011)) in which a Surrounding Gate Transistor (SGT; see Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol.38, No.3, pp.573-578 (1991)) is used as a selection transistor and a capacitor is connected, a Phase Change Memory (PCM; see, for example, H. S. Philip Wong, S. Raoux, S. Kim, Jiale Liang, J. R. Reifenberg, B. Rajendran, M. Asheghi and K. E. Goodson: "Phase Change Memory," Proceeding of IEEE, Vol.98, No 12, December, pp.2201-2227 (2010)) in which a resistance change element is connected, a Resistive Random Access Memory (RRAM; see, for example, K. Tsunoda, K .Kinoshita, H. Noshiro, Y. Yamazaki, T. Iizuka, Y. Ito, A. Takahashi, A. Okano, Y. Sato, T. Fukano, M. Aoki, and Y. Sugiyama: "Low Power and high Speed Switching of Ti-doped NiO ReRAM under the Unipolar Voltage Source of less than 3V," IEDM (2007)), a Magneto-resistive Random Access Memory (MRAM; see, for example, W. Kang, L. Zhang, J. Klein, Y. Zhang, D. Ravelosona, and W. Zhao: "Reconfigurable Codesign of STT-MRAM Under Process Variations in Deeply Scaled Technology," IEEE Transaction on Electron Devices, pp.1-9 (2015)) in which a direction of a magnetic spin is changed by a current to change resistance, and the like are known.

Furthermore, a DRAM memory cell (see Japanese Unexamined Patent Application Publication No. 3-171768, M. G. Ertosun, K. Lim, C. Park, J. Oh, P. Kirsch, and K. C. Saraswat: "Novel Capacitorless Single-Transistor Charge-Trap DRAM (1T CT DRAM) Utilizing Electron," IEEE Electron Device Letter, Vol. 31, No.5, pp.405-407 (2010), J. Wan, L. Rojer, A. Zaslavsky, and S. Critoloveanu: "A Compact Capacitor-Less High-Speed DRAM Using Field Effect-Controlled Charge Regeneration," Electron Device Letters, Vol. 35, No.2, pp.179-181 (2012), T. Ohsawa, K. Fujita, T. Higashi, Y. Iwata, T. Kajiyama, Y. Asao, and K. Sunouchi: "Memory design using a one-transistor gain cell on SOI," IEEE JSSC, vol.37, No.11, pp1510-1522 (2002)., T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: "Floating Body RAM Technology and its Scalability to 32nm Node and Beyond," IEEE IEDM (2006)., and E. Yoshida: "A Capacitorless 1T-DRAM Technology Using Gate-Induced Drain-Leakage (GIDL) Current for Low-Power and High-Speed Embedded Memory," IEEE IEDM (2006).) constituted by a single MOS transistor without a capacitor, and the like are known. In such a DRAM memory cell, logic data "1" is written, for example, by retaining, in a channel, a part or all of holes among holes and electrons generated by an impact ionization phenomenon in the channel due to a source-drain current of an N-channel MOS transistor. Then, the holes are discharged from the channel to write logic data "0". In this memory cell, "1"-written memory cell and a "0"-written memory cell are randomly present with respect to a common selection word line. When an ON voltage is applied to a selection word line, a floating body channel voltage of a selected memory cell connected to the selection word line markedly fluctuates depending on capacitive coupling between a gate electrode and a channel. In this memory cell, a problem lies in improvement of a decrease of an operation margin caused by the floating body channel voltage fluctuation and improvement of a decrease in data retention characteristics caused by discharge of a part of holes that are signal charges retained in a channel.

Furthermore, a Twin-Transistor MOS transistor memory element (see, for example, US2008/0137394 A1, US2003/0111681 A1, and F. Morishita, H. Noda, I. Hayashi, T. Gyohten, M. Okamoto, T. Ipposhi, S. Maegawa, K. Dosaka, and K. Arimoto: "Capacitorless Twin-Transistor Random Access Memory (TTRAM) on SOI," IEICE Trans. Electron., Vol. E90-c., No.4 pp.765-771 (2007)) in which a memory cell is formed on a Silicon On Insulator (SOI) layer by using two MOS transistors is known. In these elements, an N⁺ region serving as a source or a drain that separates floating body channels of the two MOS transistors is provided in contact with an insulating layer on a substrate side. This N⁺ region electrically isolates the floating body channels of the two MOS transistors. Holes that are signal charges are accumulated only in the floating body channel of one of the MOS transistors. The other MOS transistor serves as a switch for reading the signal holes accumulated in the one MOS transistor.

Furthermore, a dynamic flash memory cell 111 (see Japanese Patent No. 7057032, US2022/0208254 A1, and K.Sakui, N. Harada, "Dynamic Flash Memory with Dual Gate Surrounding Gate Transistor (SGT)," Proc. IEEE IMW, pp.72-75(2021)) constituted by an MOS transistor without a capacitor illustrated in FIGS. 7A to 7D is known. As illustrated in FIG. 7A, a floating body semiconductor substrate 102 is provided on an SiO₂ layer 101 of an SOI substrate. An N⁺ region 103 connected to a source line SL and an N⁺ region 104 connected to a bit line BL are provided at both ends of the floating body semiconductor substrate 102. Furthermore, a first gate insulating layer 109a that is connected to the N⁺ region 103 and covers the floating body semiconductor substrate 102 and a second gate insulating layer 109b that is connected to the N⁺ region 104 and is connected to the first gate insulating layer 109a with a slit insulating film 110 interposed therebetween and covers the floating body semiconductor substrate 102 are provided. Furthermore, a first gate conductive layer 105a that covers the first gate insulating layer 109a and is connected to a plate line PL and a second gate conductive layer 105b that covers the second gate insulating layer 109b and is connected to a word line WL are provided. Furthermore, the slit insulating layer 110 is provided between the first gate conductive layer 105a and the second gate conductive layer 105b. This forms a memory cell 111 of a dynamic flash memory (DFM). Note that the source line SL may be connected to the N⁺ region 104, and the bit line BL may be connected to the N⁺ region 103.

As illustrated in FIG. 7A, for example, a zero voltage is applied to the N⁺ region 103 and a positive voltage is applied to the N⁺ region 104 so that a first N channel MOS transistor region constituted by the floating body semiconductor substrate 102 covered with the first gate conductive layer 105a operates in a linear region and a second N channel MOS transistor region constituted by the floating body semiconductor substrate 102 covered with the second gate conductive layer 105b operates in a saturation region. As a result, in the second N channel MOS transistor region, no pinch-off point is present and an inversion layer 107b is formed over the entire surface. The inversion layer 107b provided on a lower side of the second gate conductive layer 105b to which the word line WL is connected works as a substantial drain of the first N channel MOS transistor region. As a result, an electric field is maximum in a boundary region of a channel region between the first N channel MOS transistor region and the second N channel MOS transistor region, and an impact ionization phenomenon occurs in this region. Then, as illustrated in FIG. 7B, a memory write operation is performed by excluding electrons among electrons and holes generated by the impact ionization phenomenon from the floating body semiconductor substrate 102 and retaining a part or all of the holes 106 in the floating body semiconductor substrate 102. This state is logic data "1".

Then, as illustrated in FIG. 7C, for example, an erase operation is performed by applying a positive voltage to the plate line PL, applying a zero voltage to the word line WL and the bit line BL, and applying a negative voltage to the source line SL and thus discharging the holes 106 from the floating body semiconductor substrate 102. This state is logic data "0". Characteristics such that a current does not flow even in a case where a voltage of the word line WL is increased in a logic data "0" read operation as illustrated in FIG. 7D is obtained by setting a voltage applied to the first gate conductive layer 105a connected to the plate line PL higher than a threshold voltage in a logic data "1" state and lower than a threshold voltage in a logic data "0" state in a data read operation. Due to the characteristics, an operation margin is markedly enlarged as compared with the memory cell. In this memory cell, channels of the first and second N channel MOS transistor regions in which the first gate conductive layer 105a connected to the plate line PL and the second gate conductive layer 105b connected to the word line WL serve as gates are connected in the floating body semiconductor substrate 102, and thus voltage fluctuation of the floating body semiconductor substrate 102 during application of a selection pulse voltage to the word line is markedly suppressed. This markedly improves the problem of decrease in operation margin in the memory cell or decrease in data retention characteristics caused by discharge of a part of holes that are signal charges accumulated in a channel. By forming a plurality of dynamic flash memory cells vertically with respect to a substrate, high integration is achieved (US2022/0208254 A1). In such a dynamic flash memory, memory cells are arranged adjacent to each other in vertical and horizontal directions, and it is therefore required to devise measures for reducing interference between adjacent memory cells and for facilitating manufacturing. In addition, further characteristic improvement and higher integration are required.

Note that in a "1" write operation, electron-hole pairs may be generated by using a gate induced drain leakage (GIDL) current described in E. Yoshida: "A Capacitorless 1T-DRAM Technology Using Gate-Induced Drain-Leakage (GIDL) Current for Low-Power and High-Speed Embedded Memory," IEEE IEDM (2006)., and a floating body (FB) may be filled with the generated holes.

### SUMMARY OF THE INVENTION

A first aspect of the present invention provides a memory device using a semiconductor element, the memory device including:

a first channel semiconductor layer and a second channel semiconductor layer that are spaced away from a substrate in a vertical direction and extend in parallel with each other in a horizontal direction;

a first impurity region and a second impurity region that are in contact with both ends of the first channel semiconductor layer;

a third impurity region and a fourth impurity region that are in contact with both ends of the second channel semiconductor layer;

a first gate insulating layer that is in contact with a vertical side surface of the first channel semiconductor layer on a side opposite to the second channel semiconductor layer;

a second gate insulating layer that is in contact with a vertical side surface of the first channel semiconductor layer on a side close to the second channel semiconductor layer;

a third gate insulating layer that is in contact with a vertical side surface of the second channel semiconductor layer on a side close to the first channel semiconductor layer;

a fourth gate insulating layer that is in contact with a vertical side surface of the second channel semiconductor layer on a side opposite to the first channel semiconductor layer;

a first gate conductive layer including one or more conductive layer portions that are in contact with the second gate insulating layer and the third gate insulating layer and are arranged in an extending direction in which the first channel semiconductor layer and the second channel semiconductor layer extend;

a second gate conductive layer including one or more conductive layer portions that are in contact with the first gate insulating layer and are arranged in the extending direction; and

a third gate conductive layer including one or more conductive layer portions that are in contact with the fourth gate insulating layer and are arranged in the extending direction, in which

the first channel semiconductor layer and the second channel semiconductor layer have a substantially identical shape and are aligned with each other when viewed in a direction perpendicular to the extending direction in which the first channel semiconductor layer and the second channel semiconductor layer extend and to the vertical direction with respect to the substrate,

a first memory cell includes the first channel semiconductor layer, the first impurity region, the second impurity region, the first gate insulating layer, the second gate insulating layer, the first gate conductive layer, and the second gate conductive layer,

a second memory cell includes the second channel semiconductor layer, the third impurity region, the fourth impurity region, the third gate insulating layer, the fourth gate insulating layer, the first gate conductive layer, and the third gate conductive layer,

the first gate conductive layer is shared by the first memory cell and the second memory cell,

the first impurity region is connected to a first source line extending in the vertical direction, and the third impurity region is connected to a second source line extending in the vertical direction,

the second and fourth impurity regions are connected to a first bit line extending in the horizontal direction, and

during a data write period and a data read period, the memory device performs a logic "1" data write or read operation in the memory cell of the first channel semiconductor layer by applying a first voltage to the first bit line, applying, to the first source line, a second voltage for causing an ON current to flow through the first channel semiconductor layer, and applying the first voltage identical to the first bit line to the second source line, and performs a logic "1" data write or read operation in the memory cell of the second channel semiconductor layer by applying the first voltage to the first bit line, applying, to the second source line, the second voltage for causing an ON current to flow through the second channel semiconductor layer, and applying the first voltage identical to the first bit line to the first source line.

The memory device may be configured such that in the logic "1" data write or read operation, a fixed voltage is held in the first gate conductive layer and the third gate conductive layer in a case where a pulse voltage is applied to the second gate conductive layer, and a fixed voltage is held in the second gate conductive layer in a case where a pulse voltage is applied to the first gate conductive layer and the third gate conductive layer.

The memory device may be configured such that the first gate conductive layer, the second gate conductive layer, and the third gate conductive layer each includes three conductive layer portions that have a substantially identical shape and are aligned with each other when viewed in the direction perpendicular to the extending direction in which the first channel semiconductor layer and the second channel semiconductor layer extend and to the vertical direction with respect to the substrate, and the conductive layer portions at both ends, in the extending direction, of each of the first gate conductive layer, the second gate conductive layer, and the third gate conductive layer are connected by a wire.

The memory device may be configured such that in plan view, positions of both ends of the second gate conductive layer and the third gate conductive layer match positions of both ends of the first gate conductive layer in the extending direction in which the first and second channel semiconductor layers extend.

The memory device may be configured such that in plan view, positions of both ends of the second gate conductive layer and the third gate conductive layer match positions of both ends of any one of the plurality of conductive layer portions of the first gate conductive layer in the extending direction in which the first and second channel semiconductor layers extend.

The memory device may be configured such that in plan view, in the extending direction in which the first and second channel semiconductor layers extend, positions of both ends of the second gate conductive layer and the third gate conductive layer are located outside positions of both ends of at least one of the conductive layer portions of the first gate conductive layer, and a position of one end or positions of both ends of the second gate conductive layer and a position of one end or positions of both ends of the third gate conductive layer are located inside positions of both ends of the conductive layer portion(s) of the first gate conductive layer other than the at least one conductive layer portion.

The memory device may be configured such that during the logic "1" data write period and the logic "1" data read period, a voltage higher than a voltage applied to the first gate conductive layer is applied to the second and third gate conductive layers in a case where signal charges are holes, and a voltage lower than the voltage applied to the first gate conductive layer is applied to the second and third gate conductive layers in a case where the signal charges are electrons.

The memory device may be configured such that during the logic "1" data write period, holes or electrons that are a signal generated due to an impact ionization phenomenon or a gate-induced drain current by a current flowing through the first channel semiconductor layer connected to the first source line or the second channel semiconductor layer connected to the second source line are accumulated in the first channel semiconductor layer or the second channel semiconductor layer.

The memory device may be configured such that a plurality of memory cell units including the first memory cell and the second memory cell are arranged so as to have an identical shape and be aligned with each other when viewed in the direction perpendicular to the extending direction in which the first channel semiconductor layer and the second channel semiconductor layer extend and to the vertical direction with respect to the substrate,

a plurality of source line groups each including every n-th source line among source lines connected to the memory cells are provided, where n is a predetermined integer greater than 1,

the source lines that constitute each of the source line groups extend in an identical direction, and the identical direction is an upward direction in the vertical direction or a downward direction in the vertical direction, and

the source line groups are connected to respective coupling source lines that correspond to the source line groups and are independent of one another.

The memory device may be configured such that the coupling source lines are located above or below the first channel semiconductor layer and the second channel semiconductor layer in the vertical direction with respect to the substrate.

The memory device may be configured such that the independent coupling source lines are placed on an identical plane parallel to the substrate above the memory cells connected to the independent coupling source lines in the vertical direction with respect to the substrate or placed on an identical plane below the memory cells in the vertical direction with respect to the substrate.

The memory device may be configured such that the independent coupling source lines are placed on a plurality of planes parallel to the substrate above the memory cells in the vertical direction with respect to the substrate or placed on a plurality of planes parallel to the substrate below the memory cells in the vertical direction with respect to the substrate.

The memory device may be configured such that during a data erase period, in a state where signal charges that are holes or electrons indicative of the logic "1" data are present in both of the first channel semiconductor layer and the second channel semiconductor layer, an operation of erasing the logic "1" data in only one of the first channel semiconductor layer and the second channel semiconductor layer is performed by performing data erasing of the signal charges that are holes or electrons indicative of the logic "1" data in both of the first channel semiconductor layer and the second channel semiconductor layer and then writing the logic "1" data again in the first channel semiconductor layer or the second channel semiconductor layer in which the logic "1" data is held.

The memory device may be configured such that during a data erase period, a plurality of memory cells including the first channel semiconductor layer and the second channel semiconductor layer constitute a single block, and the logic "1" data is written into a predetermined memory cell after block erasing is performed in which data of all of the memory cells included in the block is erased at one time.

The memory device may be configured such that during a data erase period, an identical voltage is applied to both of the first bit line and the second source line, and a voltage lower than the voltage applied to the first bit line and the second source line is applied to the first source line in a case where signal charges are holes or a voltage higher than the voltage applied to the first bit line and the second source line is applied to the first source line in a case where the signal charges are electrons.

The memory device may be configured such that in plan view, the second gate conductive layer and the third gate conductive layer are separated into two gate conductive layers at a central part in a direction orthogonal to the extending direction in which the first channel semiconductor layer and the second channel semiconductor layer extend.

The memory device may be configured such that during a period where a pulse voltage is applied to one of the two gate conductive layers separated at the central part, a fixed voltage that does not change over time is applied to the other one of the two gate conductive layers.

The memory device may be configured such that during a data retention period, a voltage identical to or lower than a voltage applied to the first gate conductive layer is applied to the second and third gate conductive layers in a case where signal charges are holes, and a voltage identical to or higher than the voltage applied to the first gate conductive layer is applied to the second and third gate conductive layers in a case where the signal charges are electrons.

The memory device may be configured such that the second gate conductive layer and the third gate conductive layer each include two isolated conductive layer portions arranged in the extending direction, and each of the two conductive layer portions of the second gate conductive layer and a corresponding one of the two conductive layer portions of the third gate conductive layer have an identical shape and are aligned with each other when viewed in the direction perpendicular to the extending direction and to the vertical direction with respect to the substrate, and

during a data retention period, a voltage applied to one of the two conductive layer portions of each of the second and third gate conductive layers is lower than a voltage applied to the other one of the two conductive layer portions in a case where signal charges are holes, and a voltage applied to one of the two conductive layer portions of each of the second and third gate conductive layers is higher than a voltage applied to the other one of the two conductive layer portions in a case where the signal charges are electrons.

The memory device may be configured such that the second gate conductive layer and the third gate conductive layer each include three isolated conductive layer portions arranged in the extending direction, and each of the three conductive layer portions of the second gate conductive layer and a corresponding one of the three conductive layer portions of the third gate conductive layer have an identical shape and are aligned with each other when viewed in the direction perpendicular to the extending direction in which the first channel semiconductor layer and the second channel semiconductor layer extend and to the vertical direction with respect to the substrate, and

during a data retention period, a voltage applied to a central one of the three conductive layer portions of each of the second and third gate conductive layers is lower than a voltage applied to the conductive layer portions at both sides in a case where signal charges are holes, and a voltage applied to a central one of the three conductive layer portions of each of the second and third gate conductive layers is higher than a voltage applied to the conductive layer portions at both sides in a case where the signal charges are electrons.

### BRIEF DESCRIPTION OF THE DRAWINGS

FIG. 1A is a three-dimensional structure diagram of a dynamic flash memory according to a first embodiment.

FIGS. 1BA, 1BB and 1BC are structure diagrams of the dynamic flash memory according to the first embodiment.

FIGS. 1CA and 1CB are diagrams for explaining data write and read operations in the dynamic flash memory according to the first embodiment.

FIG. 1D is a structure diagram of a four-row dynamic flash memory according to a modification of the first embodiment.

FIG. 2A is a three-dimensional structure diagram of a dynamic flash memory according to a second embodiment.

FIG. 2B is a structure diagram of the dynamic flash memory according to the second embodiment.

FIG. 2C is a diagram for explaining operations in the dynamic flash memory according to the second embodiment.

FIG. 3 is a structure diagram of a dynamic flash memory according to a third embodiment.

FIG. 4 is a structure diagram of a dynamic flash memory according to a fourth embodiment.

FIG. 5 is a structure diagram of a dynamic flash memory according to a fifth embodiment.

FIG. 6A is a diagram for explaining data write and read operations in another dynamic flash memory according to a sixth embodiment.

FIGS. 6BA and 6BB are diagrams for explaining data write and read operations in the dynamic flash memory according to the sixth embodiment.

FIGS. 7A, 7B, 7C and 7D are diagrams for explaining an operation principle of a conventional dynamic flash memory.

### DESCRIPTION OF THE PREFERRED EMBODIMENTS

A memory device (hereinafter referred to as a dynamic flash memory) using a semiconductor element according to an embodiment of the present invention is described with reference to the drawings.

### First Embodiment

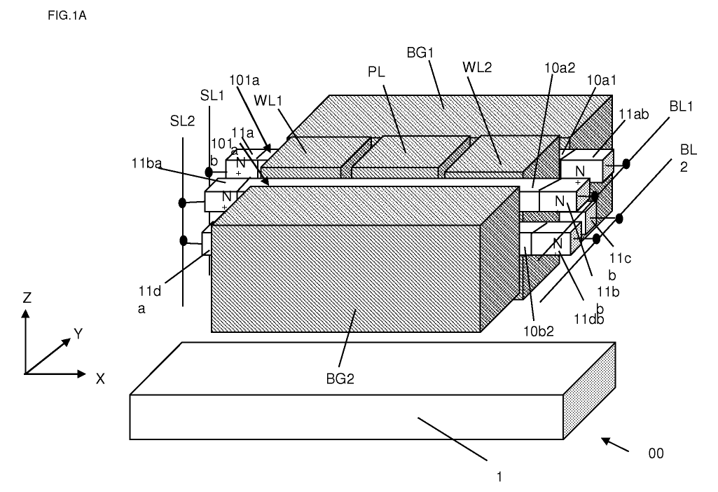

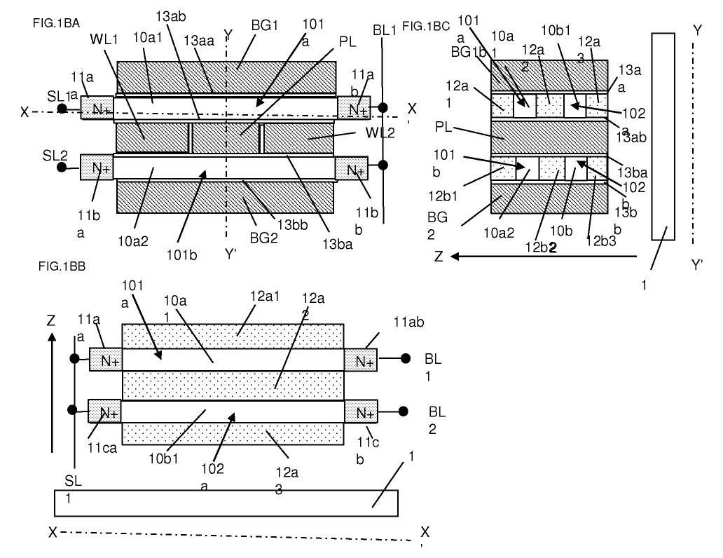

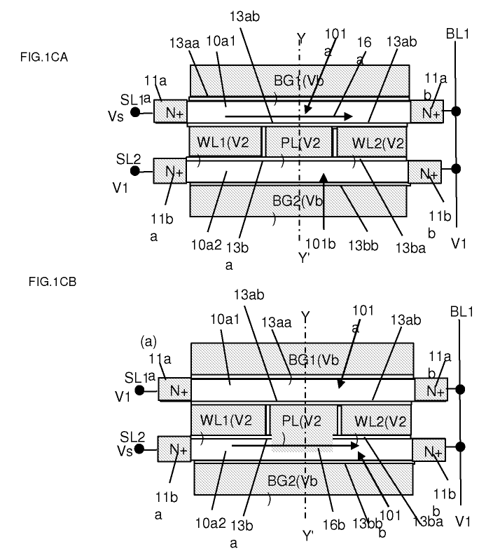

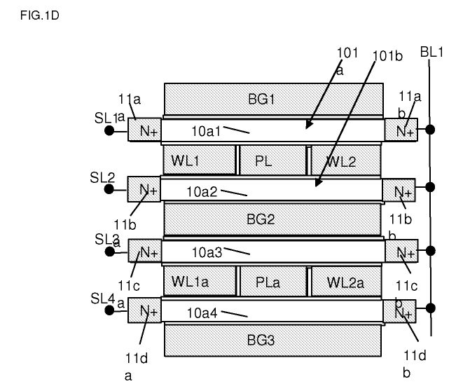

A structure, a data write operation, and a data read operation of a two-row two-stage dynamic flash memory according to a first embodiment of the present invention are described with reference to FIGS. 1A, 1BA to 1BC, and 1CA and 1CB. FIG. 1A is a three-dimensional structure diagram of a dynamic flash memory including memory cells arranged in two vertical stages and two horizontal rows. FIGS. 1BA to 1BC illustrate a plan view and a cross-sectional view of the three-dimensional structure diagram of FIG. 1A. In FIGS. 1CA and 1CB, data write and read operations are described by using two memory cells arranged within a plane parallel to a substrate surface. A structure of a four-row dynamic flash memory according to a modification of the first embodiment of the present invention is described with reference to FIG. 1D. In this modification, data write and read operations are described by using four memory cells arranged within a plane parallel to a substrate surface. In an actual dynamic flash memory, a large number of memory cells are arranged on a horizontal plane and in a vertical direction.

FIG. 1A illustrates a dynamic flash memory 100 (an example of a "memory device" of the claims) provided on a substrate 1 (an example of a "substrate" of the claims). Two P-type conductive channel semiconductor layers 10a1 (an example of a "first channel semiconductor layer" of the claims) and 10a2 (an example of a "second channel semiconductor layer" of the claims) that are spaced away from the substrate 1 in a vertical direction (Z direction) and extend in an X direction in parallel with each other on a horizontal plane (X-Y plane) are provided. Two channel semiconductor layers 10b1 (not illustrated) and 10b2 arranged in parallel with each other below the channel semiconductor layers 10a1 and 10a2 in the vertical direction are provided. In plan view, the channel semiconductor layer 10a1 and the channel semiconductor layer 10b1 have a substantially identical shape and are aligned with each other, and similarly, the channel semiconductor layer 10a2 and the channel semiconductor layer 10b2 have a substantially identical shape and are aligned with each other. Furthermore, when viewed in a direction perpendicular to the extending direction in which the channel semiconductor layer 10a1 and the channel semiconductor layer 10a2 extend and to the vertical direction with respect to the substrate 1, the channel semiconductor layer 10a1 and the channel semiconductor layer 10a2 have a substantially identical shape and are aligned with each other, and similarly, the channel semiconductor layer 10b1 and the channel semiconductor layer 10b2 have a substantially identical shape and are aligned with each other. N⁺ regions 11aa (an example of a "first impurity region" of the claims) and 11ab (an example of a "second impurity region" of the claims) containing a large amount of donor impurities are provided at both ends of the channel semiconductor layer 10a1. N⁺ regions 11ba (an example of a "third impurity region" of the claims) and 11bb (an example of a "fourth impurity region" of the claims) containing a large amount of donor impurities are provided at both ends of the channel semiconductor layer 10a2. N⁺ regions 11ca (not illustrated) and 11cb containing a large amount of donor impurities are provided at both ends of the channel semiconductor layer 10b1. N⁺ regions 11da and 11db containing a large amount of donor impurities are provided at both ends of the channel semiconductor layer 10b2. A gate insulating layer (not illustrated) is provided in contact with both side surfaces of the channel semiconductor layers 10a1 and 10a2 and the channel semiconductor layers 10b1 and 10b2. A first gate conductive layer (an example of a "first gate conductive layer" of the claims) including a first word line gate conductive layer WL1 (an example of a "conductive layer portion" of the claims), a plate line gate conductive layer PL (an example of a "conductive layer portion" of the claims), and a second word line gate conductive layer WL2 (an example of a "conductive layer portion" of the claims) that are in contact with the gate insulating layer, are sandwiched between the channel semiconductor layers 10a1 and 10b1 and the channel semiconductor layers 10a2 and 10b2, and extend in the vertical direction is provided. A first back gate conductive layer BG1 (an example of a "second gate conductive layer" and a "conductive layer portion" of the claims) that is in contact with the gate insulating layer on side surfaces of the channel semiconductor layers 10a1 and 10b1 on one side and extends in the vertical direction is provided. A second back gate conductive layer BG2 (an example of a "third gate conductive layer" and a "conductive layer portion" of the claims) that is in contact with the gate insulating layer on side surfaces of the channel semiconductor layers 10a2 and 10b2 on the other side and extends in the vertical direction is provided. In plan view, both end positions of the first and second back gate conductive layers BG1 and BG2 are located at outer end positions of the first word line gate conductive layer WL1 and the second word line gate conductive layer WL2. A memory cell 101a (an example of a "first memory cell" of the claims) is formed in a portion including the channel semiconductor layer 10a1. A memory cell 101b(an example of a "second memory cell" of the claims) is formed in a portion including the channel semiconductor layer 10a2.

The N⁺ region 11aa and the N⁺ region 11ca are connected to a first source line SL1 (an example of a "first source line" of the claims) that extends in the vertical direction. The N⁺ region 11ba and the N⁺ region 11da are connected to a second source line SL2 (an example of a "second source line" of the claims) that extends in the vertical direction. The N⁺ region 11ab and the N⁺ region 11bb are connected to a first bit line BL1 (an example of a "first bit line" of the claims) that extends in the horizontal direction. The N⁺ region 11cb and the N⁺ region 11db are connected to a second bit line BL2 that extends in the horizontal direction.

FIG. 1BA illustrates a plan view of the schematic three-dimensional diagram of the two-state dynamic flash memory cell of FIG. 1A. FIG. 1BB illustrates a vertical cross-sectional view taken along line X-X' of FIG. 1BA. FIG. 1BC illustrates a vertical cross-sectional view taken along line Y-Y' of FIG. 1BA.

As illustrated in FIGS. 1BA to 1BC, the two channel semiconductor layers 10a1 and 10a2 that are spaced apart from the substrate 1 in the vertical direction and extend in the horizontal direction in parallel with each other are provided. The two channel semiconductor layers 10b1 and 10b2 that are arranged in parallel with each other below the channel semiconductor layers 10a1 and 10a2 in the vertical direction are provided. When viewed in top view, the channel semiconductor layer 10a1 and the channel semiconductor layer 10b1 have a substantially identical shape and are aligned with each other, and similarly, the channel semiconductor layer 10a2 and the channel semiconductor layer 10b2 have a substantially identical shape and are aligned with each other. The N⁺ regions 11aa and 11ab containing a large amount of donor impurities are provided at both ends of the channel semiconductor layer 10a1. The N⁺ regions 11ba and 11bb containing a large amount of donor impurities are provided at both ends of the channel semiconductor layer 10a2. The N⁺ regions 11ca and 11cb containing a large amount of donor impurities are provided at both ends of the channel semiconductor layer 10b1. The N⁺ regions 11da and 11db containing a large amount of donor impurities are provided at both ends of the channel semiconductor layer 10b2. Insulating layers 12a1, 12a2, and 12a3 are provided above, between, and below the channel semiconductor layers 10a1 and 10b1, respectively. Insulating layers 12b1, 12b2, and 12b3 are provided above, between, and below the channel semiconductor layers 10a2 and 10b2. Gate insulating layers 13aa, 13ab, 13ba, and 13bb are provided on both side surfaces of the channel semiconductor layers 10a1 and 10b1 and the insulating layers 12a1, 12a2, and 12a3 and on both side surfaces of the channel semiconductor layers 10a2 and 10b2 and the insulating layers 12b1, 12b2, and 12b3. The gate insulating layer 13aa (an example of a "first gate insulating layer" of the claims) is located on a side opposite to the channel semiconductor layer 10a2 and is in in contact with a vertical side surface of the channel semiconductor layer 10a1, the gate insulating layer 13ab (an example of a "second gate insulating layer" of the claims) is located on a side close to the channel semiconductor layer 10a2 and is in contact with a vertical side surface of the first channel semiconductor layer 10a1, the gate insulating layer 13ba (an example of a "third gate insulating layer" of the claims) is located on a side close to the channel semiconductor layer 10a1 and is in contact with a vertical side surface of the channel semiconductor layer 10a2, and the gate insulating layer 13bb (an example of a "fourth gate insulating layer" of the claims) is located on a side opposite to the channel semiconductor layer 10a1 and is in contact with a vertical side surface of the channel semiconductor layer 10a2.

As illustrated in FIGS. 1BA to 1BC, the first word line gate conductive layer WL1, the plate line gate conductive layer PL, and the second word line gate conductive layer WL2 that are sandwiched between the channel semiconductor layers 10a1 and 10b1 and the channel semiconductor layers 10a2 and 10b2, are in contact with the gate insulating layers 13ab and 13ba, and are insulated from each other extend in the vertical direction with respect to the substrate. The first back gate conductive layer BG1 that is in contact with a surface of the gate insulating layer 13aa opposite to the channel semiconductor layers 10a1 and 10b1 and extends in the vertical direction with respect to the substrate is provided. The second back gate conductive layer BG2 that is in contact with a surface of the gate insulating layer 13bb opposite to the channel semiconductor layers 10a2 and 10b2 and extends in the vertical direction with respect to the substrate is provided. The memory cell 101a (an example of a "first memory cell" of the claims) is formed by the channel semiconductor layer 10a1, the N⁺ regions 11aa and 11ab, the gate insulating layers 13aa and 13ab, the first word line gate conductive layer WL1, the plate line gate conductive layer PL, the second word line gate conductive layer WL2, and the first back gate conductive layer BG1. The memory cell 101b (an example of a "second memory cell" of the claims) is formed by the channel semiconductor layer 10a2, the N⁺ regions 11ba and 11bb, the gate insulating layers 13ba and 13bb, the first word line gate conductive layer WL1, the plate line gate conductive layer PL, the second word line gate conductive layer WL2, and the first back gate conductive layer BG2. The first word line gate conductive layer WL1, the plate line gate conductive layer PL, and the second word line gate conductive layer WL2 are gate conductive layers common to the memory cell 101a and the memory cell 101b. A memory cell 102a that has the same shape as the memory cell 101a in plan view and is formed by the channel semiconductor layer 10b1, the N⁺ regions 11ca and 11cb, the gate insulating layers 13aa and 13ab, the first word line gate conductive layer WL1, the plate line gate conductive layer PL, the second word line gate conductive layer WL2, and the first back gate conductive layer BG1 is provided below the memory cell 101a. A memory cell 102b that has the same shape as the memory cell 101b in plan view and is formed by the channel semiconductor layer 10b2, the N⁺ regions 11da and 11db, the gate insulating layers 13ba and 13bb, the first word line gate conductive layer WL1, the plate line gate conductive layer PL, the second word line gate conductive layer WL2, and the second back gate conductive layer BG2 is provided below the memory cell 101b.

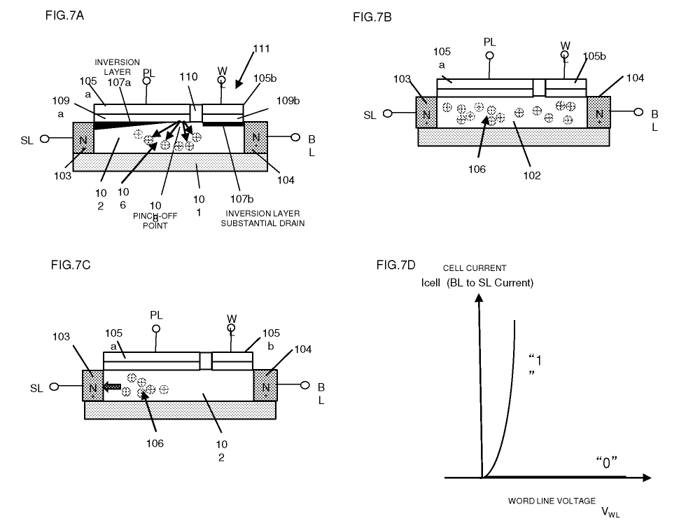

An operation of the two memory cells provided in the channel semiconductor layers 10a1 and 10a2 according to the present invention during a data write period (an example of a "data write period" of the claims) is described with reference to FIGS. 1CA and 1CB. As illustrated in FIG. 1CA, a voltage Vs is applied to the first source line SL1 connected to the N⁺ region 11aa. A positive voltage V1 is applied to the N⁺ region 11ba connected to the second source line SL2. The same positive voltage V1 as that applied to the N⁺ region 11ba is applied to the first bit line BL1 connected to the N⁺ regions 11ab and 11bb. A positive ON voltage V2 that is needed for a current to flow through the channel semiconductor layers 10a1 and 10a2 is applied to the first word line gate conductive layer WL1, the plate line gate conductive layer PL, and the second word line gate conductive layer WL2. A negative voltage Vb is applied to the back gate conductive layers BG1 and BG2. By application of the ON voltage V2 to the first word line gate conductive layer WL1, the plate line gate conductive layer PL, and the second word line gate conductive layer WL2, the memory cells of the first and second channel semiconductor layers 10a1 and 10a2 on both sides of the first word line gate conductive layer WL1, the plate line gate conductive layer PL, and the second word line gate conductive layer WL2 are simultaneously accessed. In this case, however, an ON current 16a flows through the first channel semiconductor layer 10a1 by application of a voltage (V1 - Vs) between the N⁺ regions 11aa and 11ab, but no current flows through the second channel semiconductor layer 10a2 between the N⁺ regions 11ba and 11bb to which the same V1 is applied (OFF state), as illustrated in FIG. 1CA. As a result, only the memory cell of the first channel semiconductor layer 10a1 is accessed. In this case, Vs, V1, V2, and Vb are set to such voltages that holes that are a signal are generated by the ON current 16a due to an impact ionization phenomenon similar to that described with reference to FIGS. 7A to 7D or a GIDL current. In the first and second channel semiconductor layers 10a1 and 10b1, holes that are signal charges in data "1" are accumulated close to the first back gate conductive layer BG1. In the case of data "0", no holes are accumulated.

Next, as illustrated in FIG. 1CB, the voltage applied to the first source line SL1 is set to V1 and the voltage applied to the second source line SL2 is set to Vs while keeping the voltage applied to the first word line gate conductive layer WL1, the plate line gate conductive layer PL, and the second word line gate conductive layer WL2 at V2 and keeping the voltage applied to the first bit line BL1 at V1. As a result, only the memory cell of the second channel semiconductor layer 10a2 is accessed. In a data "1" write operation, a current 16b flows between the N⁺ regions 11ba and 11bb, and data "1" is set by holes generated by an impact ionization phenomenon or a GIDL current. In a data "0" write operation, no current flows. As a result, "1" or "0" data is written into only the memory cell of the second channel semiconductor layer 16b although the first word line gate conductive layer WL1, the plate line gate conductive layer PL, and the second word line gate conductive layer WL2 are gates common to the first and second channel semiconductor layers 10a1 and 10b2. In the "0" data write operation, Vs, V1, V2, and Vb are set to such voltages that no holes are generated by the ON current 16a due to an impact ionization phenomenon or a GIDL current. Note that it is only necessary to perform a data "1" write operation in a case where a refresh operation of first writing "0" data into the first and second channel semiconductor layers 16a and 16b is performed.

An operation mechanism of the two memory cells formed in the channel semiconductor layers 10a1 and 10a2 during a data read period (an example of a "data read period" of the claims) is basically identical to the data write operation described above. In the data write operation, the voltages are set so that holes that are a signal are generated by the current 16a or 16b due to impact ionization or a GIDL current in the channel semiconductor layer 10a1 or 10a2 during data "1" writing. On the other hand, in the data read operation, holes are not generated by the current 16a or 16b due to impact ionization or a GIDL current.

The ON voltage V2 is applied to the first word line gate conductive layer WL1, the plate line gate conductive layer PL, and the second word line gate conductive layer WL2. The memory cells of the first and second channel semiconductor layers 10a1 and 10a2 on both sides of the first word line gate conductive layer WL1, the plate line gate conductive layer PL, and the second word line gate conductive layer WL2 are simultaneously accessed. In this case, however, the ON current 16a flows through the first channel semiconductor layer 10a1 by application of (V1 - Vs) between the N⁺ regions 11aa and 11ab, as illustrated in FIG. 1CA. No current flows through the second channel semiconductor layer 10a2 between the N⁺ regions 11ba and 11bb to which the same V1 is applied (OFF state). As a result, only the memory cell of the channel semiconductor layer 10a1 is accessed. Note that in the case of data "0", in which holes that are signal charges are not accumulated in the first channel semiconductor layer 10a1, the above "1" current does not flow (OFF state). As a result, the logic data "1" or "0" in only the first channel semiconductor layer 10a1 is read.

Next, as illustrated in FIG. 1CB, the voltage applied to the first source line SL1 is set to V1 and the voltage applied to the second source line SL2 is set to Vs while keeping the voltage applied to the first word line gate conductive layer WL1, the plate line gate conductive layer PL, and the second word line gate conductive layer WL2 at V2 and keeping the voltage applied to the first bit line BL1 at V1. As a result, only the memory cell of the second channel semiconductor layer 10a2 is accessed. The "1" current 16b flows between the N⁺ regions 11ba and 11bb in the data "1" state, and no current flows in the data "0" state. As a result, only the memory cell of the second channel semiconductor layer 10a2 is accessed and the logic data "1" or "0" in only the second channel semiconductor layer 10a2 is read although the first word line gate conductive layer WL1, the plate line gate conductive layer PL, and the second word line gate conductive layer WL2 are gates common to the first and second channel semiconductor layers 10a1 and 10b2.

FIG. 1D illustrates a dynamic flash memory in which memory cells (memory cells including channel semiconductor layers 10a3 and 10a4) having a similar structure to the memory cells including the channel semiconductor layers 10a1 and 10a2 illustrated in FIGS. 1BA to 1BC are placed adjacent in plan view. N⁺ regions 11ca and 11cb are located at both ends of the channel semiconductor layer 10a3, and N⁺ regions 11da and 11db are located at both ends of the channel semiconductor layer 10a4. A first word line gate conductive layer WL1a, a plate line gate conductive layer PLa, and a second word line gate conductive layer WL2a that are sandwiched between gate insulating layers and are isolated by an insulating layer are provided between the channel semiconductor layers 10a3 and 10a4. A third back gate conductive layer BG3 is provided below the channel semiconductor layer 10a4. That is, the word line and plate line gate conductive layers and the back gate conductive layers are provided above and below the channel semiconductor layers 10a1, 10a2, 10a3, and 10a4. Therefore, the word line and plate line gate conductive layers and the back gate conductive layers are gate conductive layers of the channel semiconductor layer of the two memory cells provided above and below these gate conductive layers. High integration of the memory cells is thus achieved.

In a data erase operation in the memory cells illustrated in FIG. 1D, signal holes in the channel semiconductor layers 10a2 and 10a3 on both sides of the back gate conductive layer BG2 are discharged, for example, in a case where a positive voltage is applied to the back gate conductive layer BG2. In a case where only signal holes in the channel semiconductor layer 10a2 or 10a3 are discharged, signal holes need be written into the other channel semiconductor layer by some method.

In a state where signal holes of logic "1" data are present in both of the channel semiconductor layers 10a2 and 10a3, there are three methods for leaving the signal holes of logic "1" data in one of the channel semiconductor layers 10a2 and 10a3. According to the first method, an operation of writing the logic "1" data into one of the channel semiconductor layers 10a2 and 10a3 again is performed after an operation of erasing the signal holes in both of the channel semiconductor layers 10a2 and 10a3 is performed. According to the second method, in a case where block erase in which data in memory cells arranged in horizontal and vertical directions are simultaneously erased is performed, data in all of the memory cells in the block are erased to a logic "0" data state, and data is written only in a memory cell of logic "1" data. According to the third method, for example, in a case where the signal holes in the channel semiconductor layer 10a3 are retained and the signal holes in the channel semiconductor layer 10a2 are removed, a first voltage higher than a potential of the channel semiconductor layer 10a3 in which the signal holes are present and having the same potential is applied to the bit line BL1 and the source line SL3. As a result, the signal holes accumulated in the channel semiconductor layer 10a3 do not flow out through the source line SL3 and the bit line BL1. A second voltage lower than the first voltage and lower than the potential of the channel semiconductor layer 10a is applied to the source line SL2. This discharges the signal holes in the first channel semiconductor layer 10a2 through the source line SL2. The signal holes in the channel semiconductor layer 10a3 can be removed and the signal holes in the channel semiconductor layer 10a2 can be retained by a similar method. The same applies to the other embodiments.

Note that although an example in which the first to third gate conductive layers WL1, PL, and WL2 are provided has been described in the first embodiment described with reference to FIGS. 1A, 1BA to 1BC, and 1CA and 1CB, the above operations are similarly applied to a structure constituted by the first and second gate conductive layers WL1 and PL. This will be described later.

In plan view, each of the back gate conductive layers BG1, BG2, and BG3 may be divided into a plurality of portions (e.g., two or three portions) in a direction in which the channel semiconductor layers 10a1 to 10a4 extend. In plan view, each of the back gate conductive layers BG1, BG2, and BG3 may be divided into two back gate conductive layers that are insulated from each other in a direction orthogonal to the direction in which the channel semiconductor layers 10a1 to 10a4 extend. In this case, the divided two back gate conductive layers can be driven independently of each other. The same applies to the other embodiments.

Not only a fixed voltage, but also a time-varying pulse voltage may be applied to the back gate conductive layers BG1 and BG2. In this case, the first word line gate conductive layer WL1, the plate line gate conductive layer PL, and the second word line gate conductive layer WL2 may be, for example, given a role as electrostatic shield electrodes to which a fixed voltage of 0 V is applied.

In FIGS. 1BA to 1BC, an example in which the gate insulating layers 13ab and 13ba that are continuous are provided in contact with both sides of the first and second word line gate conductive layers WL1 and WL2 and the plate line gate conductive layer PL in plan view is illustrated. On the other hand, each of the gate insulating layers 13ab and 13ba may be configured so that a portion thereof corresponding to the first word line gate conductive layer WL1, a portion thereof corresponding to the second word line gate conductive layer WL2, and a portion thereof corresponding to the plate line gate conductive layer PL are separate from each other. The same applies to the other embodiments.

During the logic "1" data write period and the logic "1" data read period, a voltage lower than the voltage applied to the first and second word line gate conductive layers WL1 and WL2 and the plate line gate conductive layer PL may be applied to the back gate conductive layers BG1 and BG2. The signal holes are thus accumulated in regions of the channel semiconductor layers 10a1 and 10a2 close to the back gate conductive layers BG1 and BG2. A place where the signal holes are accumulated can be thus separated away from data write and read current paths. This enables more stable data write and read operations. Note that in a case where the signal charges are electrons, a voltage higher than the voltage applied to the first and second word line gate conductive layers WL1 and WL2 and the plate line gate conductive layer PL need just be applied to the back gate conductive layers BG1 and BG2 during the logic "1" data write period and the logic "1" data read period.

During the data retention period of the memory illustrated in FIGS. 1BA to 1BC, the voltage applied to the back gate conductive layers BG1 and BG2 may be kept lower than the voltage applied to the first and second word line gate conductive layers WL1 and WL2 and the plate line gate conductive layer PL. The holes that are signals can be thus retained in regions of the channel semiconductor layers close to the back gate conductive layers BG1 and BG2. This enables a stable operation. Note that in a case where the signal charges are electrons, the voltage applied to the back gate conductive layers BG1 and BG2 need just be kept higher than the voltage applied to the first and second word line gate conductive layers WL1 and WL2 and the plate line gate conductive layer PL.

The present embodiment has the following features.
1. As illustrated in FIG. 1A, in the dynamic flash memory according to the present invention, the first word line gate conductive layer WL1, the plate line gate conductive layer PL, and the second word line gate conductive layer WL2 are gates common to the first and second channel semiconductor layers 10a1 and 10a2. This enables high integration of the memory cells in plan view.
2. As illustrated in FIG. 1D, in the dynamic flash memory according to the present invention, the back gate conductive layer BG2 is also a gate common to the second channel semiconductor layer 10a2 and the third channel semiconductor layer 10a3. That is, according to the present invention, the gate conductive layers WL1, PL, WL2, WLa, PLa, and WL2a and the back gate conductive layers BG1, BG2, and BG3 are gates common to the upper and lower memory cells in plan view. This enables high integration of the memory cells in plan view.
3. As illustrated in FIGS. 1CA and 1CB, according to the present invention, the holes that are signal charges can be accumulated in regions of the first channel semiconductor layer 10a1 and the second channel semiconductor layer 10a2 close to the back gate conductive layers BG1 and BG2. The holes that are signal charges can be thus separated away from the data read currents 16a and 16b, and "1" data degradation caused by decrease in signal holes during data read can be prevented.
4. The back gate conductive layers BG1 and BG2 can be given a role as an electrostatic shield conductive layer. Furthermore, in a case where a pulse voltage is applied to the back gate conductive layers BG1 and BG2, the first word line gate conductive layer WL1, the plate line gate conductive layer PL, and the second word line gate conductive layer WL2 can be given a role as an electrostatic shield conductive layer by applying a fixed voltage (e.g., 0 V) to the first word line gate conductive layer WL1, the plate line gate conductive layer PL, and the second word line gate conductive layer WL2. This contributes to stable operation and characteristic improvement of the dynamic flash memory.

### Second Embodiment

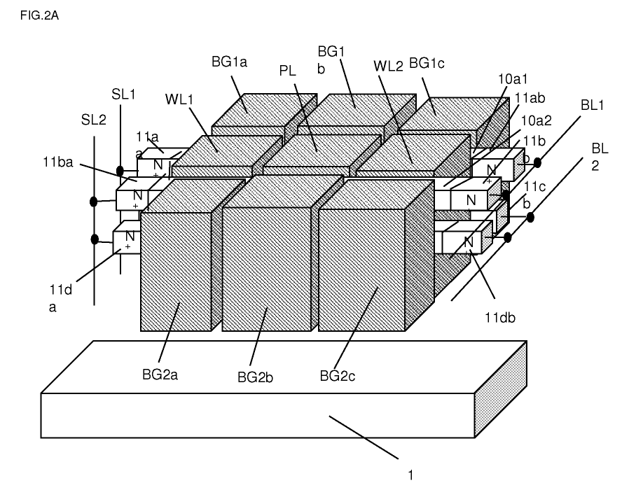

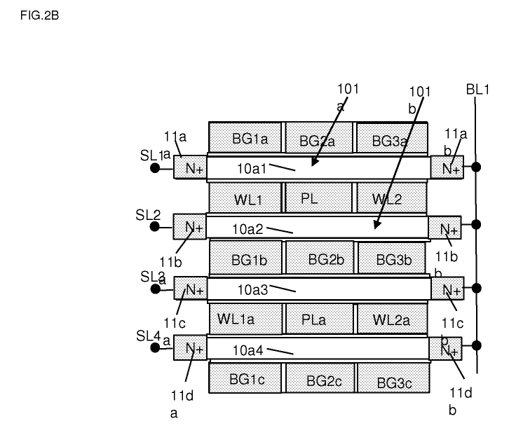

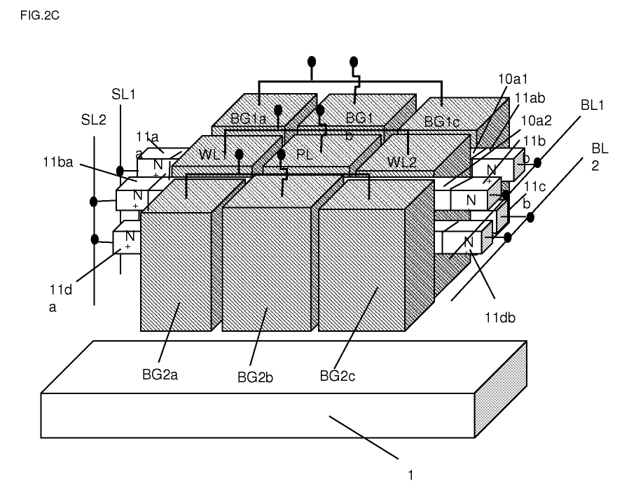

A structure and drive of a dynamic flash memory according to a second embodiment of the present invention are described with reference to FIGS. 2A, 2B, and 2C,.

In the memory cells illustrated in FIG. 1, the first word line gate conductive layer WL1, the plate line gate conductive layer PL, and the second word line gate conductive layer WL2 are separate in the direction in which the channel semiconductor layers 10a1 and 10b2 extend, whereas the back gate conductive layers BG1 and BG2 that face the first word line gate conductive layer WL1, the plate line gate conductive layer PL, and the second word line gate conductive layer WL2 are not divided. On the other hand, as illustrated in FIG. 2, the back gate conductive layer BG1 of FIG. 1 is divided into back gate conductive layers BG1a, BG1b, and BG1c, and the back gate conductive layer BG2 of FIG. 1 is divided into back gate conductive layers BG2a, BG2b, and BG2c.

In the dynamic flash memory illustrated in FIG. 2B, BG1 illustrated in FIG. 1D is divided into three back gate conductive layers BG1a, BG2a, and BG3a, BG2 is divided into three back gate conductive layers BG1b, BG2b, and BG3b, and BG3 is divided into three back gate conductive layers BG1c, BG2c, and BG3c. In the dynamic flash memory according to the present embodiment, first word line gate conductive layers WL1 and WL1a, plate line gate conductive layers PL and PLa, second word line gate conductive layers WL2 and WL2a, and the back gate conductive layers BG1a to BG1c, BG2a to BG2c, and BG3a to BG3c that have the same shape are provided on both sides of first to fourth channel semiconductor layers 10a1, 10a2, 10a3, and 10a4. In the description using FIGS. 1CA and 1CB, and 1D, the back gate conductive layers BG1 to BG3 serve to accumulate holes that are signal charges in regions of the channel semiconductor layers 10a1 to 10a4 close to the back gate conductive layers BG1 to BG3 and have a role as an electrostatic shield electrode. On the other hand, in the dynamic flash memory according to the present embodiment, in a data erase operation, holes that are a signal are discharged from N⁺ layers 11aa to 11da and/or N⁺ layers 11ab to 11db by applying a positive voltage pulse (e.g., 1.5 V) to the back gate conductive layers BG2a, BG2b, and BG2c and applying a voltage (e.g., 0 V) lower than the voltage applied to the back gate conductive layers BG2a, BG2b, and BG2c to the gate conductive layers BG1a, BG3a, BG1b, BG3b, BG1c, and BG3c. In this case, the first word line gate conductive layers WL1 and WL1a, the plate line gate conductive layers PL and PLa, and the second word line gate conductive layers WL2 and WL2a can be given a role as an electrostatic shield electrode by keeping a state where a fixed voltage (e.g., 0 V) lower than the voltage applied to the back gate conductive layers BG2a, BG2b, and BG2c is applied to the first word line gate conductive layers WL1 and WL1a, the plate line gate conductive layers PL and PLa, and the second word line gate conductive layers WL2 and WL2a.

As described above, by applying a positive pulse voltage to one of (i) the first word line gate conductive layers WL1 and WL1a, the plate line gate conductive layers PL and PLa, and the second word line gate conductive layers WL2 and WL2a and (ii) the back gate conductive layers BG1a to BG1c, BG2a to BG2c, and BG3a to BG3c and applying a fixed voltage lower than the positive pulse voltage to the other one of (i) the first word line gate conductive layers WL1 and WL1a, the plate line gate conductive layers PL and PLa, and the second word line gate conductive layers WL2 and WL2a and (ii) the back gate conductive layers BG1a to BG1c, BG2a to BG2c, and BG3a to BG3c, the conductive layers to which the fixed voltage is applied can be given a role as an electrostatic shield electrode. In a case where the signal charges are electrons, by applying a negative pulse voltage to one of (i) the first word line gate conductive layers WL1 and WL1a, the plate line gate conductive layers PL and PLa, and the second word line gate conductive layers WL2 and WL2a and (ii) the back gate conductive layers BG1a to BG1c, BG2a to BG2c, and BG3a to BG3c and applying a fixed voltage higher than the positive pulse voltage to the other one of (i) the first word line gate conductive layers WL1 and WL1a, the plate line gate conductive layers PL and PLa, and the second word line gate conductive layers WL2 and WL2a and (ii) the back gate conductive layers BG1a to BG1c, BG2a to BG2c, and BG3a to BG3c, the conductive layers to which the fixed voltage is applied can be given a role as an electrostatic shield electrode.

During a data retention period and a data read period, for example, a negative voltage is applied to the back gate conductive layers BG2a, BG2b, and BG2c, and for example, 0 V is applied to the back gate conductive layers BG1a, BG3a, BG1b, BG3b, BG1c, and BG3c. Holes that are signal charges can thus be accumulated in regions of the channel semiconductor layers 10a1 to 10a4 close to BG2a, BG2b, and BG2c away from the N⁺ regions 11aa to 11da and 11ab to 11db.

As illustrated in FIG. 2C, the back gate conductive layers BG1a and BG1c may be connected, the first word line gate conductive layer WL1 and the second word line gate conductive layer WL2 may be connected, and the back gate conductive layers BG2a and BG2c may be connected. This also enables normal operation of the dynamic flash memory. This is also advantageous in that the number of drive lines to the outside can be reduced.

In FIG. 2B, the divided back gate conductive layers BG1a, BG1b, and BG1c, back gate conductive layers BG2a, BG2b, and BG2c, and back gate conductive layers BG3a, BG3b, and BG3c can be driven by different waveform voltages.

During the data retention period in the memory illustrated in FIG. 2A, a voltage lower than a voltage applied to the back gate conductive layers BG1a, BG1c, BG2a, and BG2c on both sides of the back gate conductive layers BG1b and BG2b is applied to the back gate conductive layers BG1b and BG2b. Holes that are signal charges can thus be retained in the channel semiconductor layer regions 10a1 to 10db close to the back gate conductive layers BG1b and BG2b away from the N⁺ regions 11aa to 11db. This enables a stable data read operation. Note that in a case where the signal charges are electrons, a voltage higher than the voltage applied to the back gate conductive layers BG1a, BG1c, BG2a, and BG2c on both sides of the back gate conductive layers BG1b and BG2b is applied to the back gate conductive layers BG1b and BG2b during the data retention period. The same applies the other embodiments.

### Third Embodiment

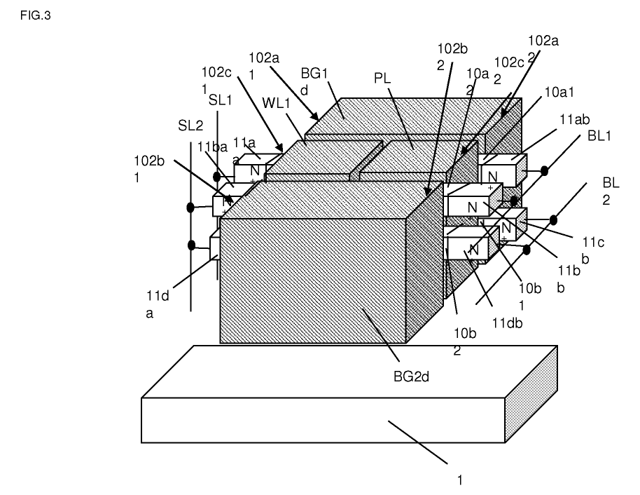

FIG. 3 is a structure diagram of a two-row and two-stage dynamic flash memory according to a third embodiment of the present invention.

In the memory cells illustrated in FIG. 1, the first word line gate conductive layer WL1, the plate line gate conductive layer PL, and the second word line gate conductive layer WL2 are provided in the direction in which the channel semiconductor layers 10a1 to 10b2 extend. On the other hand, the first gate conductive layer may have a structure excluding the second word line gate conductive layer WL2, as illustrated in FIG. 3. In plan view, both ends 102a1, 102a2, 102b1, and 102b2 of back gate conductive layers BG1d and BG2d are located at same positions as an end portion 102c1 of a first word line gate conductive layer WL1 on a source line side and an end portion 102c2 of a plate line gate conductive layer PL on a first bit line side in a direction in which channel semiconductor layers 10a1 to 10b2 extend. This also enables normal operation of the dynamic flash memory, as is understood from the conventional example of FIGS. 7A to 7D and the first embodiment of FIGS. 1A to 1C. Operations identical to those described with reference to FIGS. 1A to 1C are performed. Note that in the case of the two-gate conductive layer structure including the word line gate conductive layer WL1 and the plate line gate conductive layer PL illustrated in FIG. 3, the positions of the word line gate conductive layer WL1 and the plate line gate conductive layer PL in the direction in which the channel semiconductor layers 10a1 to 10b2 extend may be reverse.

### Fourth Embodiment

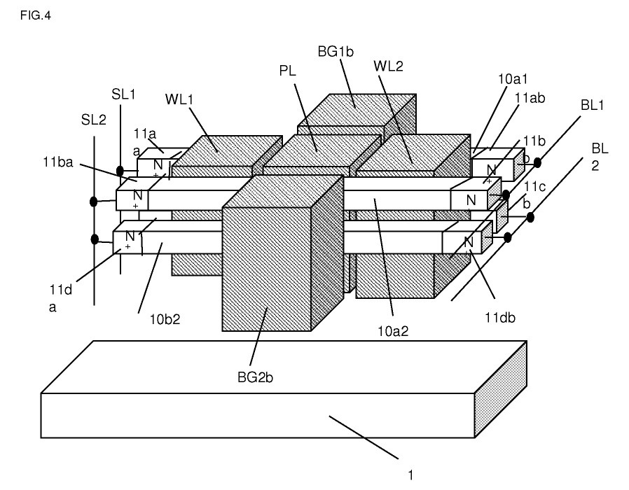

FIG. 4 is a structure diagram of a two-row and two-stage dynamic flash memory according to a fourth embodiment of the present invention.

As illustrated in FIG. 4, in plan view, both ends of back gate conductive layers BG1b and BG2b are located at positions of both ends of a plate line gate conductive layer PL in a direction in which channel semiconductor layers 10a1 to 10b2 extend. When viewed in a vertical cross section, the back gate conductive layers BG1b and BG2b overlap the plate line gate conductive layer PL. This makes it possible to separate the back gate conductive layers BG1b and BG2b from N⁺ regions 11aa to 11da connected to source lines SL1 and SL2 whose voltages change and N⁺ regions 11ab to 11db connected to bit lines BL1 and BL2. This decreases capacitive coupling between the back gate conductive layers BG1b and BG2b and the N⁺ regions 11aa to 11da. This contributes to stable operation of the dynamic flash memory. Note that similar effects can be obtained even in a case where the back gate conductive layers BG1b and BG2b overlap the first word line gate conductive layer WL1 or the second word line gate conductive layer WL2. In particular, in a memory cell constituted by the first word line gate conductive layer WL1 and the plate line gate conductive layer PL, the positions of the back gate conductive layers BG1b and BG2b change depending on which conductive layer side signal charges are accumulated.

### Fifth Embodiment

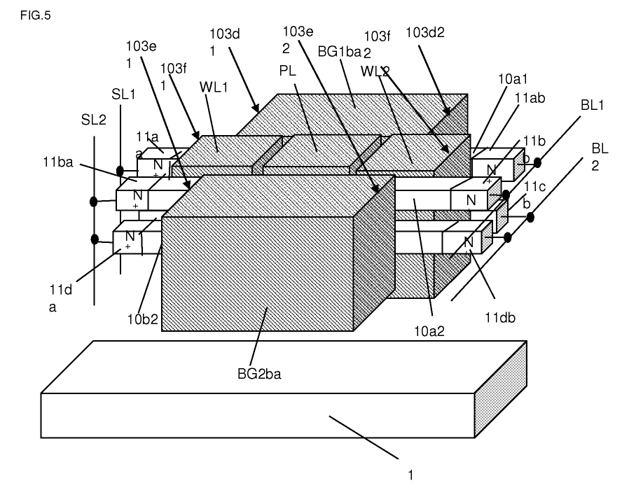

FIG. 5 is a structure diagram of a two-row and two-stage dynamic flash memory according to a fifth embodiment of the present invention.

As illustrated in FIG. 5, in plan view, both ends 103d1, 103d2, 103e1, and 103e2 of back gate conductive layers BG1ba and BG2ba are located inward of positions of outer end portions 103f1 and 103f2 of word line gate conductive layers WL1 and WL2 in a direction in which channel semiconductor layers 10a1 to 10b2 extend. This makes it possible to increase the number of holes that are signal charges accumulated in the channel semiconductor layers 10a1 to 10b2 as compared with the dynamic flash memory described with reference to FIG. 4. Furthermore, capacitive coupling between N⁺ regions 11aa to 11da and the back gate conductive layers BG1b and BG2b can be reduced as compared with the dynamic flash memory described with reference to FIG. 1. This enables stable operation of the dynamic flash memory. Note that similar effects are obtained even in a case where a positions of one end of each of the back gate conductive layers BG1ba and BG2ba matches one end of the plate line gate conductive layer PL in plan view. Note that although FIG. 5 illustrates a three-gate conductive layer structure including the word line gate conductive layers WL1 and WL2 and the plate line gate conductive layer PL, the present embodiment is also applicable to a two-gate conductive layer structure including the word line gate conductive layer WL1 and the plate line gate conductive layer PL illustrated in FIG. 3. In this case, one end 102a1, 102a2, 102b1, or 102b2 of each of the back gate conductive layers BG1d and BG2d in plan view is located between the one end 102c1 of the word line gate conductive layer WL1 close to the N⁺ regions 11aa to 11da and the one end 102c2 of the plate line gate conductive layer PL close to the N⁺ regions 11ab to 11db.

### Sixth Embodiment

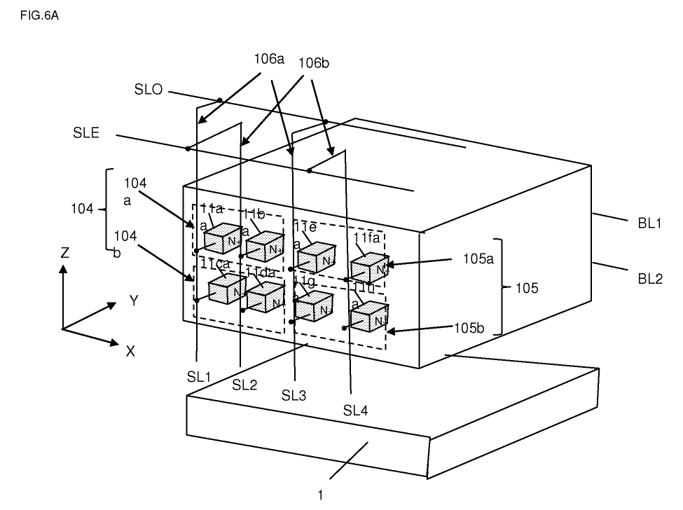

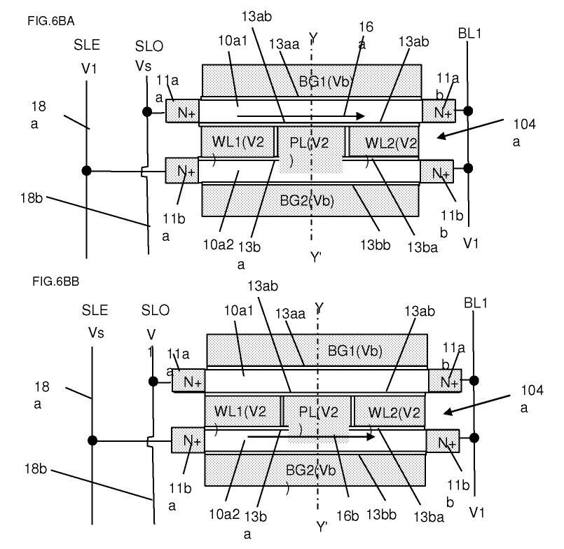

Data write and read operations of memory cells according to a sixth embodiment of the present invention are described with reference to FIGS. 6A, and 6BA and 6BB.

FIG. 6A illustrates an aspect in which a memory cell unit group 104 in which a memory cell unit 104a including N⁺ regions 11aa and 11ba and a memory cell unit 104b including N⁺ regions 11ca and 11da are arranged in two stages similar to that illustrated in FIG. 1A and a memory cell unit group 105 having a similar structure including a memory cell unit 105a including N⁺ regions 11ea and 11fa and a memory cell unit 105b including N⁺ regions 11ga and 11ha are arranged adjacent in a horizontal direction (X direction). The memory cell unit 104a including the N⁺ regions 11aa and 11ba and the memory cell unit 105a including the N⁺ regions 11ea and 11fa have a substantially identical shape and are aligned with each other when viewed in a direction perpendicular to a direction in which a channel semiconductor layer including the N⁺ region 11aa and a channel semiconductor layer including the N⁺ region 11ba extend and to a vertical direction with respect to a substrate 1. The memory cell unit 104b including the N⁺ regions 11ca and 11da and the memory cell unit 105b including the N⁺ regions 11ga and 11ha have a substantially identical shape and are aligned with each other when viewed in a direction perpendicular to a direction in which a channel semiconductor layer including the N⁺ region 11ca and a channel semiconductor layer including the N⁺ region 11da extend and to the vertical direction with respect to the substrate 1. BL1 connected to the N⁺ regions 11ab and 11bb in FIG. 1A is connected to an N⁺ region (not illustrated) at one end of each of channel semiconductor layers (not illustrated) connected to the N⁺ regions 11ea and 11fa and extends in the horizontal direction (X direction) with respect to the substrate 1. BL2 connected to the N⁺ regions 11cb and 11db in FIG. 1A is connected to an N⁺ region (not illustrated) at one end of each of channel semiconductor layers (not illustrated) connected to the N⁺ regions 11ga and 11ha and extends in the horizontal direction (X direction) with respect to the substrate 1. In FIGS. 1CA and 1CB of the first embodiment, the source line SL1 connected to the N⁺ region 11aa and the source line SL2 connected to the N⁺ region 11ba extend upward in the vertical direction (Z direction) with respect to the substrate 1 and are independently extracted separately from other source lines. The source lines SL1 and SL2 are accessed independently of other source lines. On the other hand, in the present embodiment, a source line SL1 connected to the N⁺ regions 11aa and 11ca and a source line SL3 connected to the N⁺ regions 11ea and 11ga are connected to a coupling source line SLO on an upper side. A source line SL2 connected to the N⁺ regions 11ba and 11da and a source line SL4 connected to the N⁺ regions 11fa and 11ha are connected to a coupling source line SLE on an upper side in the vertical direction (Z direction). That is, a source line group 106a including odd-numbered source lines SL1 and SL3 and a source line group 106b including even-numbered source lines SL2 and SL4 are provided, the source line SL1 and the source line SL3 that constitute the source line group 106a extend in the same direction, that is, upward in the vertical direction (Z direction) and are connected to the coupling source line SLO, and the source line SL2 and the source line SL4 that constitute the source line group 106b extend in the same direction, that is, upward in the vertical direction (Z direction) and are connected to the coupling source line SLE. Although the source lines SL1 to SL4 also extend in the vertical direction (Z direction) with respect to the substrate 1 and are independently extracted in the present embodiment, the source line group 106a (the source lines SL1 and SL3) is connected to the coupling source line SLO at extracted upper ends, and the source line group 106b (SL2 and SL4) is connected to the coupling source line SLE independent of the coupling source line SLO at extracted upper ends.

FIGS. 6BA and 6BB are diagrams for explaining a data write operation or a data read operation in memory cells connected to the N⁺ regions 11aa and 11ba among the memory cells illustrated in FIG. 6A. In the data write operation or the data read operation, for example, a voltage Vs is applied to the coupling source line SLO connected to odd-numbered memory cells and a positive voltage V1 is applied to the coupling source line SLE connected to even-numbered memory cells, as illustrated in FIG. 6BA. Thus, the memory cell of the channel semiconductor layer 10a1 and other memory cells connected to the source line SLO are simultaneously accessed. In this case, no ON voltage is applied to first and second word line gate conductive layers and a plate line gate conductive layer of the other memory cells, and therefore a current flows through only the memory cell of the first channel semiconductor layer, and logic "1" is written or read in the memory cell of the first channel semiconductor layer. When the voltage V1 is applied to the coupling source line SLO and the voltage Vs is applied to the coupling source line SLE, a current flows through only the memory cell of the second channel semiconductor layer 10a2, and logic "1" is written or read in the memory cell of the second channel semiconductor layer 10a2. In the memory cells of FIGS. 1CA and 1CB, the number of coupling source lines extracted to the outside is the number of source lines arranged in a direction in which the bit line BL1 extends in plan view. On the other hand, in the present embodiment, the number of source lines extracted to the outside is only two, specifically, the coupling source line SLO connected to the odd-numbered memory cells and the coupling source line SLE connected to the even-numbered memory cells. This simplifies external circuit connection.

Note that the coupling source lines SLO and SLE may be provided above or below, in the vertical direction (Z direction), the group of memory cells including N⁺ regions 11aa, 11ba, 11ca, 11da, 11ea, 11fa, 11ga, and 11ha connected to the coupling source lines SLO and SLE. Although the coupling source lines SLO and SLE are provided on an identical plane (a plane parallel with the X-Y plane) parallel to the substrate on an upper side in the vertical direction (Z direction) in FIG. 6A, the coupling source lines SLO and SLE may be provided apart from each other in the vertical direction (Z direction). In this case, the coupling source lines SLO and SLE can be provided so as to overlap each other in plan view (when viewed in a direction orthogonal to the X-Y direction). This can increase a degree of memory cell integration.

In FIGS. 6A, and 6BA and 6BB, the source lines SL1 and SL3 connected to odd-numbered memory cells among the memory cells arranged in parallel with the substrate are connected to the coupling source line SLO, and the source lines SL2 and SL4 connected to even-numbered memory cells are connected to the coupling source line SLE. In the present embodiment, an example in which a source line group constituted by every other source line is connected to an independent source line has been described above. Source line groups each constituted by every n-th source line where n is an integer greater than 1, for example, every third or every fourth source line may be connected to a plurality of coupling source lines that correspond to the respective source line groups and are independent of one another. This reduces load capacitance of each coupling source line, thereby achieving a reduction in electric power consumption.

### Other Embodiments

In FIG. 1A, a material of the first and second word line gate conductive layers WL1 and WL2, a material of the plate line gate conductive layer PL, and a material of the first and second back gate conductive layers BG1 and BG2 may be identical or may be different. The same applies to the other embodiments.

In FIGS. 1A and 1CA and 1CB, a case where the first to fourth channel semiconductor layers 10a1, 10a2, 10b1, and 10b2 accumulate holes as signal charges by using P-type conductivity has been described. On the other hand, the first to fourth channel semiconductor layers 10a1, 10a2, 10b1, and 10b2 may accumulate electrons as signal charges by using N-type conductivity. In this case, P⁺ regions are used as the N⁺ regions 11ab to 11db. The same applies to the other embodiments.

Furthermore, various embodiments and modifications of the present invention are possible without departing from the broad spirit and scope of the present invention. The above embodiments are merely illustrative examples for explaining the present invention and are not intended to limit the scope of the present invention. The above embodiments and modifications may be combined with one another as appropriate. In addition, some of the constituent elements of the above embodiments may be omitted as necessary without departing from the technical spirit of the present invention.

According to a memory device using a semiconductor element according to the present invention, a high-density and high-performance memory device can be obtained.

What is claimed is:

1. A memory device using a semiconductor element, the memory device comprising:
a first channel semiconductor layer and a second channel semiconductor layer that are spaced away from a substrate in a vertical direction and extend in parallel with each other in a horizontal direction;
a first impurity region and a second impurity region that are in contact with both ends of the first channel semiconductor layer;
a third impurity region and a fourth impurity region that are in contact with both ends of the second channel semiconductor layer;
a first gate insulating layer that is in contact with a vertical side surface of the first channel semiconductor layer on a side opposite to the second channel semiconductor layer;
a second gate insulating layer that is in contact with a vertical side surface of the first channel semiconductor layer on a side close to the second channel semiconductor layer;
a third gate insulating layer that is in contact with a vertical side surface of the second channel semiconductor layer on a side close to the first channel semiconductor layer;
a fourth gate insulating layer that is in contact with a vertical side surface of the second channel semiconductor layer on a side opposite to the first channel semiconductor layer;
a first gate conductive layer including one or more conductive layer portions that are in contact with the second gate insulating layer and the third gate insulating layer and are arranged in an extending direction in which the first channel semiconductor layer and the second channel semiconductor layer extend;
a second gate conductive layer including one or more conductive layer portions that are in contact with the first gate insulating layer and are arranged in the extending direction; and
a third gate conductive layer including one or more conductive layer portions that are in contact with the fourth gate insulating layer and are arranged in the extending direction, wherein
the first channel semiconductor layer and the second channel semiconductor layer have a substantially identical shape and are aligned with each other when viewed in a direction perpendicular to the extending direction in which the first channel semiconductor layer and the second channel semiconductor layer extend and to the vertical direction with respect to the substrate,
a first memory cell includes the first channel semiconductor layer, the first impurity region, the second impurity region, the first gate insulating layer, the second gate insulating layer, the first gate conductive layer, and the second gate conductive layer,
a second memory cell includes the second channel semiconductor layer, the third impurity region, the fourth impurity region, the third gate insulating layer, the fourth gate insulating layer, the first gate conductive layer, and the third gate conductive layer,
the first gate conductive layer is shared by the first memory cell and the second memory cell,
the first impurity region is connected to a first source line extending in the vertical direction, and the third impurity region is connected to a second source line extending in the vertical direction,
the second and fourth impurity regions are connected to a first bit line extending in the horizontal direction, and
during a data write period and a data read period, the memory device performs a logic "1" data write or read operation in the memory cell of the first channel semiconductor layer by applying a first voltage to the first bit line, applying, to the first source line, a second voltage for causing an ON current to flow through the first channel semiconductor layer, and applying the first voltage identical to the first bit line to the second source line, and performs a logic "1" data write or read operation in the memory cell of the second channel semiconductor layer by applying the first voltage to the first bit line, applying, to the second source line, the second voltage for causing an ON current to flow through the second channel semiconductor layer, and applying the first voltage identical to the first bit line to the first source line.

2. The memory device according to claim 1, wherein
in the logic "1" data write or read operation, a fixed voltage is held in the first gate conductive layer and the third gate conductive layer in a case where a pulse voltage is applied to the second gate conductive layer, and a fixed voltage is held in the second gate conductive layer in a case where a pulse voltage is applied to the first gate conductive layer and the third gate conductive layer.

3. The memory device according to claim 1, wherein
the first gate conductive layer, the second gate conductive layer, and the third gate conductive layer each includes three conductive layer portions that have a substantially identical shape and are aligned with each other when viewed in the direction perpendicular to the extending direction in which the first channel semiconductor layer and the second channel semiconductor layer extend and to the vertical direction with respect to the substrate, and the conductive layer portions at both ends, in the extending direction, of each of the first gate conductive layer, the second gate conductive layer, and the third gate conductive layer are connected by a wire.

4. The memory device according to claim 1, wherein
in plan view, positions of both ends of the second gate conductive layer and the third gate conductive layer match positions of both ends of the first gate conductive layer in the extending direction in which the first and second channel semiconductor layers extend.

5. The memory device according to claim 1, wherein
in plan view, positions of both ends of the second gate conductive layer and the third gate conductive layer match positions of both ends of any one of the plurality of conductive layer portions of the first gate conductive layer in the extending direction in which the first and second channel semiconductor layers extend.

6. The memory device according to claim 1, wherein
in plan view, in the extending direction in which the first and second channel semiconductor layers extend, positions of both ends of the second gate conductive layer and the third gate conductive layer are located outside positions of both ends of at least one of the conductive layer portions of the first gate conductive layer, and a position of one end or positions of both ends of the second gate conductive layer and a position of one end or positions of both ends of the third gate conductive layer are located inside positions of both ends of the conductive layer portion(s) of the first gate conductive layer other than the at least one conductive layer portion.

7. The memory device according to claim 1, wherein
during the logic "1" data write period and the logic "1" data read period, a voltage higher than a voltage applied to the first gate conductive layer is applied to the second and third gate conductive layers in a case where signal charges are holes, and a voltage lower than the voltage applied to the first gate conductive layer is applied to the second and third gate conductive layers in a case where the signal charges are electrons.

8. The memory device according to claim 1, wherein
during the logic "1" data write period, holes or electrons that are a signal generated due to an impact ionization phenomenon or a gate-induced drain current by a current flowing through the first channel semiconductor layer connected to the first source line or the second channel semiconductor layer connected to the second source line are accumulated in the first channel semiconductor layer or the second channel semiconductor layer.

9. The memory device according to claim 1, wherein
a plurality of memory cell units including the first memory cell and the second memory cell are arranged so as to have an identical shape and be aligned with each other when viewed in the direction perpendicular to the extending direction in which the first channel semiconductor layer and the second channel semiconductor layer extend and to the vertical direction with respect to the substrate,
a plurality of source line groups each including every n-th source line among source lines connected to the memory cells are provided, where n is a predetermined integer greater than 1,
the source lines that constitute each of the source line groups extend in an identical direction, and the identical direction is an upward direction in the vertical direction or a downward direction in the vertical direction, and
the source line groups are connected to respective coupling source lines that correspond to the source line groups and are independent of one another.

10. The memory device according to claim 9, wherein
the coupling source lines are located above or below the first channel semiconductor layer and the second channel semiconductor layer in the vertical direction with respect to the substrate.

11. The memory device according to claim 9, wherein
the independent coupling source lines are placed on an identical plane parallel to the substrate above the memory cells connected to the independent coupling source lines in the vertical direction with respect to the substrate or placed on an identical plane below the memory cells in the vertical direction with respect to the substrate.

12. The memory device according to claim 9, wherein
the independent coupling source lines are placed on a plurality of planes parallel to the substrate above the memory cells in the vertical direction with respect to the substrate or placed on a plurality of planes parallel to the substrate below the memory cells in the vertical direction with respect to the substrate.

13. The memory device according to claim 1, wherein
during a data erase period, in a state where signal charges that are holes or electrons indicative of the logic "1" data are present in both of the first channel semiconductor layer and the second channel semiconductor layer, an operation of erasing the logic "1" data in only one of the first channel semiconductor layer and the second channel semiconductor layer is performed by performing data erasing of the signal charges that are holes or electrons indicative of the logic "1" data in both of the first channel semiconductor layer and the second channel semiconductor layer and then writing the logic "1" data again in the first channel semiconductor layer or the second channel semiconductor layer in which the logic "1" data is held.

14. The memory device according to claim 1, wherein
during a data erase period, a plurality of memory cells including the first channel semiconductor layer and the second channel semiconductor layer constitute a single block, and the logic "1" data is written into a predetermined memory cell after block erasing is performed in which data of all of the memory cells included in the block is erased at one time.

15. The memory device according to claim 1, wherein
during a data erase period, an identical voltage is applied to both of the first bit line and the second source line, and a voltage lower than the voltage applied to the first bit line and the second source line is applied to the first source line in a case where signal charges are holes or a voltage higher than the voltage applied to the first bit line and the second source line is applied to the first source line in a case where the signal charges are electrons.

16. The memory device according to claim 1, wherein
in plan view, the second gate conductive layer and the third gate conductive layer are separated into two gate conductive layers at a central part in a direction orthogonal to the extending direction in which the first channel semiconductor layer and the second channel semiconductor layer extend.

17. The memory device according to claim 16, wherein
during a period where a pulse voltage is applied to one of the two gate conductive layers separated at the central part, a fixed voltage that does not change over time is applied to the other one of the two gate conductive layers.

18. The memory device according to claim 1, wherein
during a data retention period, a voltage identical to or lower than a voltage applied to the first gate conductive layer is applied to the second and third gate conductive layers in a case where signal charges are holes, and a voltage identical to or higher than the voltage applied to the first gate conductive layer is applied to the second and third gate conductive layers in a case where the signal charges are electrons.

19. The memory device according to claim 1, wherein
the second gate conductive layer and the third gate conductive layer each include two isolated conductive layer portions arranged in the extending direction, and each of the two conductive layer portions of the second gate conductive layer and a corresponding one of the two conductive layer portions of the third gate conductive layer have an identical shape and are aligned with each other when viewed in the direction perpendicular to the extending direction and to the vertical direction with respect to the substrate, and
during a data retention period, a voltage applied to one of the two conductive layer portions of each of the second and third gate conductive layers is lower than a voltage applied to an other one of the two conductive layer portions in a case where signal charges are holes, and a voltage applied to one of the two conductive layer portions of each of the second and third gate conductive layers is higher than a voltage applied to an other one of the two conductive layer portions in a case where the signal charges are electrons.

20. The memory device according to claim 1, wherein
the second gate conductive layer and the third gate conductive layer each include three isolated conductive layer portions arranged in the extending direction, and each of the three conductive layer portions of the second gate conductive layer and a corresponding one of the three conductive layer portions of the third gate conductive layer have an identical shape and are aligned with each other when viewed in the direction perpendicular to the extending direction in which the first channel semiconductor layer and the second channel semiconductor layer extend and to the vertical direction with respect to the substrate, and
during a data retention period, a voltage applied to a central one of the three conductive layer portions of each of the second and third gate conductive layers is lower than a voltage applied to the conductive layer portions at both sides in a case where signal charges are holes, and a voltage applied to a central one of the three conductive layer portions of each of the second and third gate conductive layers is higher than a voltage applied to the conductive layer portions at both sides in a case where the signal charges are electrons.
